(19) United States
(12) Patent Application Publication
(10) Pub. No.: US 2019/0164779 A1
(43) Pub. Date: May 30, 2019

(54) CORROSION-RESISTANT SOLID-STATE PHOTO-ELECTRODE

(71) Applicant: International Business Machines Corporation, Armonk, NY (US)

(72) Inventors: Bahman Hekmatshoartabari, White Plains, NY (US); Ali Afzali-Ardakani, Ossining, NY (US); Oki Gunawan, Westwood, NJ (US); Ghavam G. Shahidi, Pound Ridge, NY (US)

(21) Appl. No.: 15/825,361

(22) Filed: Nov. 29, 2017

(51) Int. Cl. H01L 21/3213; H01L 21/02

(52) U.S. Cl. CPC H01L 21/32138; H01L 21/02499; H01L 21/02123

(57) ABSTRACT

Embodiments of the present invention provide systems and methods for constructing photo-electrodes. Hydrogenated crystalline silicon is disposed over an absorption layer, wherein the hydrogenated crystalline silicon is attached to self-assembled monolayers (SAMs). Metal electrodes are disposed over the SAMs. Surface passivation is achieved by the hydrogenated crystalline silicon and the SAMs. Resistance to surface corrosion is provided by the SAMs.

### BACKGROUND OF THE INVENTION

The present invention relates generally to semiconductor fabrication, and more specifically to semiconductor electrodes for electrochemical photolysis.

Semiconductor device fabrication is a series of processes used to create integrated circuits present in electronic devices, such as computers. Silicon (Si) is most frequently used as a semiconducting material. Si is a relatively low cost material used for semiconductor device fabrication and has potential for high energy conversion efficiency. Electrolysis of water is the decomposition of water into oxygen and hydrogen gas due to an electric current being passed through the water. This technique can be used to make hydrogen fuel (hydrogen gas) and breathable oxygen. An electrical power source is connected to two electrodes, or two plates, which are placed in the water. Hydrogen is generated at the cathode (where electrons enter the water), and oxygen is generated at the anode. At the negatively charged cathode, a reduction reaction takes place, with electrons from the cathode being given to hydrogen cations to form hydrogen gas. At the positively charged anode, an oxidation reaction occurs, generating oxygen gas and giving electrons to the anode.

In photo-electrolysis (photolysis) the required electric field may be provided by illumination. Since water is essentially transparent to the wavelengths of interest (e.g. sunlight), at least one of the anode and the cathode electrodes is required to be photosensitive (hence referred to as the photo-anode and photo-cathode, respectively). Under illumination, electron-hole pairs are generated in at least one photo-electrode (photo-anode or photo-cathode). Holes react with water molecules generating hydrogen cations and oxygen molecules at the (photo-) anode; and the hydrogen cations react with electrons and generate hydrogen molecules at the (photo-) cathode. A photo-electrode may be comprised of silicon (preferably n-type for a photo-anode, and preferably p-type for a photo-cathode); however, silicon is not stable in aqueous solutions.

### SUMMARY

According to one embodiment of the present invention, a method for constructing a photo-electrode is disclosed. The method comprises: providing an absorption layer comprised of a semiconductor material; epitaxially growing a hydrogenated silicon layer on the absorption layer using chemical vapor deposition; forming a plurality of self-assembled monolayers (SAMs) on the hydrogenated silicon layer; and coating the plurality of SAMs with one or more metals.

Another embodiment of the present invention provides a photo-electrode, which contains an absorption layer, wherein the absorption layer is comprised of a silicon-type material; a plurality of self-assembled monolayers (SAMs) disposed on the absorption layer; and a metal electrode disposed on a surface of the plurality of SAMs.

Another embodiment of the present invention provides a photo-anode, which contains an absorption layer, wherein the absorption layer is comprised of a semiconductor-type material; a hydrogenated crystalline silicon containing layer disposed on the absorption layer; a plurality of self-assembled monolayers (SAMs) disposed on the hydrogenated crystalline silicon layer; and a metal electrode disposed on a surface of the plurality of SAMs.

### BRIEF DESCRIPTION OF THE DRAWINGS

FIG. 1 is a block diagram of a photo-electrode and the accompanying energy diagram, in accordance with an embodiment of the present invention;

FIG. 2 is an example diagram of self-assembled monolayer addition to a silicon surface, in accordance with an embodiment of the present invention;

FIG. 3 is an example diagram of a symmetric test structure and the accompanying photo-conductance decay (PCD) results, in accordance with an embodiment of the present invention;

FIG. 4 is an example diagram of photo-electrode test structure and the accompanying electrical current-voltage characteristics of the test structure under illumination, in accordance with an embodiment of the present invention; and

FIG. 5 is an operational flow chart depicting the functional steps to construct a photo-electrode, in accordance with an embodiment of the present invention.

### DETAILED DESCRIPTION

Silicon (Si) is widely used in the manufacturing of semiconductor devices including photovoltaic (solar) cells with high energy-conversion efficiency. Given the maturity of the fabrication technology, and also the abundance and low cost, Si is a particularly appealing semiconductor material for use as a solid-state photo-electrode. However, Si is not stable in aqueous (particularly acidic) solutions required for photolysis, due to surface corrosion. Corrosion resistant coatings have been applied on the surface of Si. However, these coatings hamper the transport of electric charge carriers (i.e., holes and electrons) therefore reducing the performance of a photo-electrode and the conversion efficiency. For instance, epitaxially grown strontium titanium oxide (SrTiO₃) has close to zero conduction band offsets with Si and therefore, minimal impact on electron transport in a Si-based photo-cathode. However, applying SrTiO₃, which is grown on Si on (001)-plane (hereinafter Si (001)) by molecular beam epitaxy (MBE), has the disadvantages of being an expensive process that has slow deposition rates compared to other epitaxy methods and limited industrial applications in specialized instances. In addition to the high expenses of MBE, MBE precludes the use of textured surfaces (typically terminated to Si (001)-planes), wherein the textured surfaces are able to increase/improve light absorption in comparison to non-textured surfaces. Embodiments of the present invention disclose methods and systems involving a photo-electrode comprising: (i) self-assembled monolayers (SAMs) of long-chained alcohols or thiols to provide resistance to surface corrosion; (ii) a hydrogenated crystalline Si layer by chemical vapor deposition (CVD) at low temperatures (below 450° C., and preferably 150-250° C.) to facilitate majority carrier collection and/or reduce minority carrier recombination; (iii) a silicon (Si) substrate; and (iv) textured surfaces, which in turn improves light absorption. The Si photocathode disclosed herein is a low cost semiconducting technology which avoids MBE grown layers, while exhibiting energy efficiency and independence from the surface orientation of Si; and is also applicable to other semiconductors besides Si.

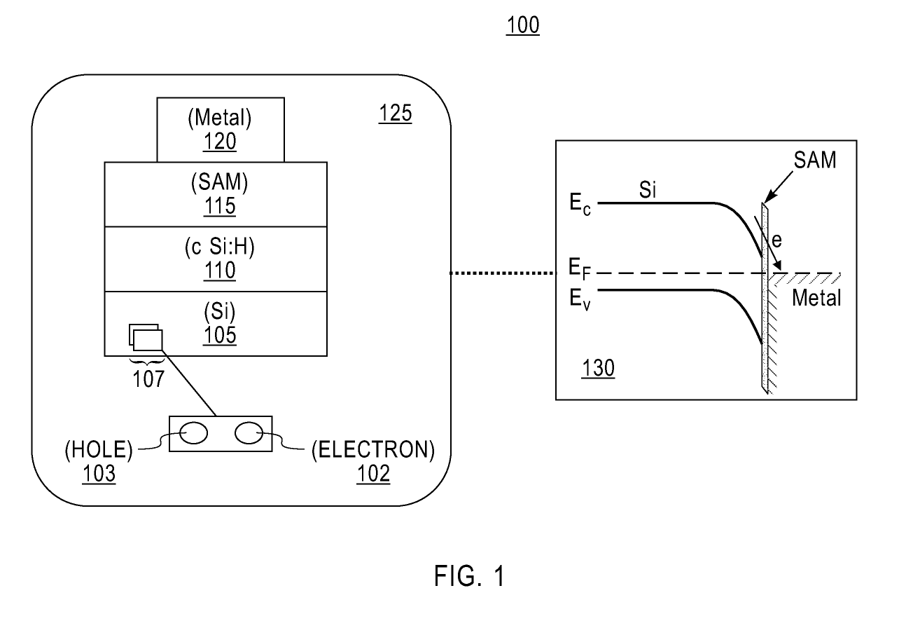

The present invention will now be described in detail with reference to the Figures. FIG. 1 is a block diagram of a semiconductor fabrication environment, in accordance with an embodiment of the present invention. FIG. 1 provides only an illustration of implementation and does not imply any limitations with regard to the environments in which different embodiments may be implemented.

Photo-electrode environment 100 depicts block diagrams of components necessary to implement the methods and systems as disclosed by the embodiments of the present invention. Additional types of components may be used without departing from the scope of the invention as recited by the claims. Electronic components, which are not explicitly depicted in FIG. 1, can be arranged in particular configurations in conjunction with other wires, voltage sources, data sources, etc. Photo-electrode environment 100 depicts the structure of the photo-electrode (e.g., photo-electrode 125) and the corresponding energy level diagram (e.g., energy diagram 130). Energy diagram 130 is an illustrative energy level diagram representing a Si-derived absorption layer doped with p-type dopant (e.g., layer 105). Photo-electrode environment 100 is suitable for functioning as a photo-cathode, in one or more embodiments. It will be appreciated that, in other embodiments, the Si-derived absorption layer (e.g., layer 105) may include n-type dopant and therefore suitable for use as a photo-anode. The photo-anode is not depicted in FIG. 1.

In an exemplary embodiment, photo-electrode 125 contains the following: layer 105; layer 110; layer 115; and layer 120. In another exemplary embodiment, layer 110 is an optional layer of photo-electrode 125. When layer 110 is excluded from photo-electrode 125, photo-electrode 125 contains layer 105, layer 115, and layer 120. Layer 105 is a semiconducting substrate, which may contain Si; layer 110 is comprised of hydrogenated crystalline silicon (c-Si:H); layer 115 is a self-assembled monolayer (SAM) deriving from a long-chain alcohol or thiol; and layer 120 is a metal.

Layer 105 is a photo-sensitive semiconducting substrate (i.e. absorption layer) where one or more units of electron-hole pair 107 are generated under illumination (e.g., sunlight). Electron-hole pair 107 is the combination of a negatively charged carrier (i.e. electron 102); and a positively charged carrier (i.e., hole 103). Freely moving units of electron 102 (i.e., mobile negative charges) and freely moving units of hole 103 (i.e., mobile positive charges) facilitate the conduction of an electric current. The more abundant charge carriers are referred to as “majority carriers”, whereas the less abundant charge carriers are referred to as “minority carriers”. In p-type semiconducting systems, the majority carriers are holes; and the minority carriers are electrons. In n-type semiconducting systems, the majority carriers are electrons; and the minority carriers are holes. In the illustrative embodiment shown in FIG. 1, layer 105 (e.g., an absorption layer) is comprised of Si. However, in other embodiments is comprised of: (i) other elemental semiconductors besides Si, such as germanium (Ge) and silicon germanium (SiGe); or (ii) III-V semiconductors, such as gallium arsenide (GaAs) and gallium nitride (GaN). In some embodiments, layer 105 is a high purity, polycrystalline form of silicon. In other embodiments, layer 105 is a monocrystalline form of silicon. In an exemplary embodiment, layer 110 is doped with p-type dopants where layer 105 is doped with n-type dopants. In another exemplary embodiment, layer 110 is doped with n-type dopants where layer 105 is doped with p-type dopants. In yet another exemplary embodiment, layer 110 is intrinsic (i.e., undoped), and layer 105 is doped with either n-type or p-type dopant.

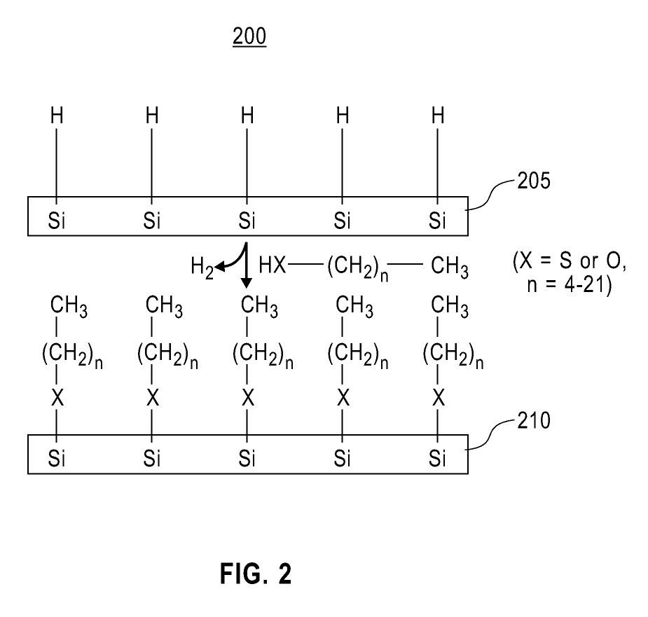

Layer 110 is an optional hydrogenated crystalline silicon (c-Si:H) layer disposed over layer 105 in order to achieve surface passivation of an absorption layer (layer 105) and therefore reduce minority carrier recombination. Surface passivation may include chemical passivation (e.g. termination of Si dangling bonds with H), field-induced passivation (e.g. repulsion of minority carriers by the electric field generated from an energy band-offset), or both. In an exemplary embodiment, layer 110 comprises of a c-Si:H layer with a thickness in the range of 3-25 nanometers (nm). Layer 110 may be thinner or thicker than the range between 3-25 nm. Plasma-enhanced chemical vapor deposition (PECVD) is used to deposit the layer 110 (c-Si:H), where PECVD is a chemical vapor deposition (CVD) process used to deposit thin films from a gas state to a solid state on a substrate (e.g., layer 105). Other CVD techniques, e.g. hot-wire CVD may also be used in some embodiments. Layer 105 may be grown using a gas mixture which may include SiH₄ (or other gases of the SiₓH_{y family}), carrier H₂ gas, and dopant gas, such as PH₃ for n-type doping and B₂H₆ or TMB (trimethylboron) for p-type doping. The c-Si:H layer (e.g., layer 110) is grown epitaxially on the absorption layer (e.g., layer 105), i.e. the crystalline structure of layer 110 follows the crystalline structure of layer 105. In one exemplary embodiment, layer 110 is monocrystalline silicon when layer 105 is monocrystalline silicon. In another exemplary embodiment, layer 110 is polycrystalline silicon when layer 105 is polycrystalline silicon. The c-Si:H layer (e.g., layer 110) may contain 5-40 atomic percent hydrogen (not explicitly depicted in FIG. 1 or FIG. 2). Layer 110, as depicted in FIG. 1 (or layer 105, in embodiments where layer 110 is not present), are furnished with a self-assembled monolayer (SAM), layer 115 of a long-chain alcohol or a long-chain thiol. In preferred embodiments, the top surface of a c-Si:H layer (e.g., layer 110) is substantially passivated with H bonds after growth, and the SAM may be readily applied to the c-Si:H surface; however, techniques known in the art, such as dipping in dilute hydrofluoric acid (HF) may also be used to improve H passivation. In contrast, in embodiments where the c-Si:H layer (e.g., layer 110) is not present, the top surface of the absorption layer (e.g., layer 105) contains a thin layer of native oxide, which may be removed using techniques known in the art, such as dipping in dilute HF, leaving a hydrogen passivated surface. As illustrated in FIG. 2, the SAM is then applied to the H passivated surface of silicon 205 (i.e., the c-Si:H layer). In some embodiments, the Si-derived absorption layer (e.g., layer 105) is passivated if the c-Si:H layer is not present.

Layer 115 contains self-assembled monolayers (SAMs) that derives from long-chained alcohols or thiols. These long-chained alcohols are structurally represented as CH₃—(CH₂)ₙ—OH, where n=4-21; and the long-chained thiols are structurally represented as CH₃—(CH₂)ₙ—SH, where n=4-21. As known in the art, Si surfaces are reactive toward proteic compounds like alcohol and thiol, and thus combine with the long-chained alcohols and long-chained thiols, respectively. More specifically, the H passivated silicon surface of the silicon 205, as depicted in FIG. 2, react with long-chained alcohols and long-chained thiols. This results in: (i) the formation of ether (CH₃—(CH₂)ₙ—O—Si) and thio-ether (CH₃—(CH₂)ₙ—S—Si) linkages of layer 115 to the silicon surface of silicon 205 from the long-chained alcohol and long-chained thiol, respectively; and (ii) the evolution of hydrogen gas (H₂).

Layer 120 is a metal layer coated over portions of layer 115. Layer 120 may include but is not limited to aluminum (Al), titanium (Ti), chromium (Cr), platinum (Pt), nickel (Ni), and combinations thereof. Layer 120 may comprise of two or more metal layers and may be nano-patterned or nano-structured. In one example, layer 120 may include a metal catalyst, for example nanostructured Ti/Pt. Energy diagram 130 depicts the effect of the SAM layer (e.g., layer 115) on the tunneling barrier for charge carriers. In an exemplary embodiment, as depicted in energy diagram 130, the conduction band edge is denoted as E_{C}; the valence band edge is denoted as E_{V}; the band gap is the difference between E_{C} and E_{V}; and Fermi level is denoted as E_{F}. The interface that occurs between two layers or regions of dissimilar semiconductors is referred to as a heterojunction. Band offsets, which describe the relative alignment of the energy bands at a semiconductor heterojunction, may influence or even hinder charge carrier transport by creating an energy barrier. The tunneling probability across an energy barrier is reduced (i.e. the tunneling barrier is increased) by increasing the height and/or the length (thickness) of the energy barrier. In an exemplary embodiment, given that the SAM (e.g., layer 115) is very thin, the tunneling barrier for electron transport is low despite a finite conduction band-offset between Si and the SAM, thus allowing efficient transport of electrons from the conduction band in Si to Fermi level in metal, as shown schematically in the energy diagram 130 of FIG. 1.

FIG. 2 is an example diagram of self-assembled monolayer (SAM) addition to a silicon surface, in accordance with an embodiment of the present invention.

Silicon surface 200 depicts the formation of a self-assembled monolayer (SAM) on the surface of hydrogenated crystalline silicon. Silicon 205 corresponds to the c-Si:H layer (e.g., layer 110), or the Si-derived absorption layer (e.g., layer 105) in embodiments where c-Si:H is not used. When corresponding to c-Si:H layer (e.g., layer 110), the silicon 205 may include hydrogen (not explicitly shown). The top surface of silicon 205 is hydrogen-terminated, as described earlier, as a result of hydrogen incorporation during growth and/or by dilute HF treatment. In an exemplary embodiment, the Si—H bonds can react with HX—(CH₂)ₙ—CH₃, where X═O or S; and n=4-21 in order to create Si—X—(CH₂)ₙ—CH₃. In some embodiments, silyl-ether or silyl-thio-ether bonds are furnished in silicon 210, respectively while evolving hydrogen gas (H₂), where X═O or S, This reaction may take place, for instance, by immersing silicon 205 in a reagent comprised of a long-chain alcohol or thiol, in more or more embodiments. In one example, silicon 205 is immersed in 1-dodecanol at temperatures ranging from 90° C. to 150° C. In an exemplary embodiment, silicon 210 includes hydrogenated crystalline silicon (c-Si:H) doped with n-type dopants and self-assembled monolayers attached to a silicon surface via silo-ether or thio-ether bonds, where c-Si:H is disposed over an absorption layer doped with p-type dopants (not depicted in FIG. 2). In another exemplary embodiment, silicon 210 includes hydrogenated crystalline silicon (c-Si:H) doped with p-type dopants and self-assembled monolayers attached to a silicon surface via silo-ether or thio-ether bonds, where a c-Si:H layer is disposed over an absorption layer doped with n-type dopants (not depicted in FIG. 2).

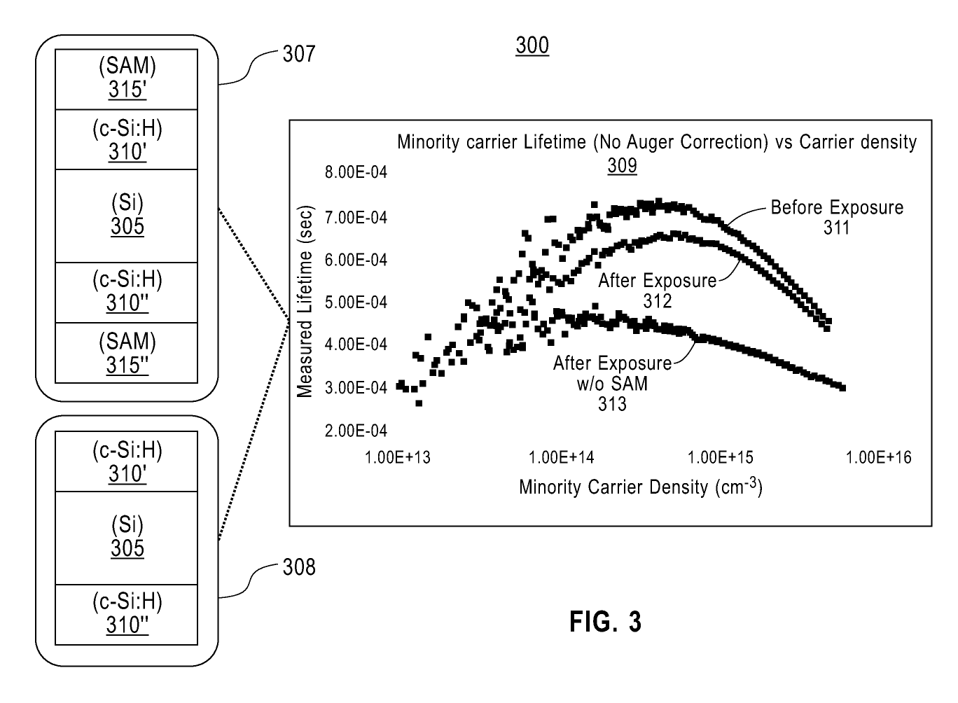

FIG. 3 is an example diagram of a symmetric test structure and the accompanying photo-conductance decay (PCD) results, in accordance with an embodiment of the present invention.

Test experiment 300 contains structures 307 and 308 for measuring effective minority carrier lifetime using quasi-steady-state photo-conductance decay (Q_{SS}-PCD) to investigate surface passivation. Graph 309 is a plot of effective minority carrier lifetime (with no Auger correction) as a function of minority carrier density, measured by Q_{SS}-PCD.

Structure 307 is a symmetric structure with layer 305 (i.e., an absorption layer identical to layer 105); layer 310′ and layer 310″ (i.e., c-Si:H identical to layer 110); and layer 315′ and layer 315″ (i.e., a SAM identical to layer 115). Layer 315′ is disposed over layer 310′, wherein layer 310′ is disposed over layer 305, wherein layer 305 is disposed over layer 310″, and wherein layer 310″ is disposed over 315″. Structure 308 is the same structure 307 except that layers 315′ and 315″ are not present. In this example, layer 305 is comprised of single-crystalline p-type Si, and the c-Si:H layer is n⁺ doped.

The effective minority carrier lifetime of structure 307 measured by Q_{SS}-PCD is indicated by line 311 in graph 309. The effective minority carrier lifetime of structure 308 was also measured by Q_{SS}-PCD and was found to be nearly identical to graph 309, and therefore not plotted in graph 309. This result indicates that, in this example, n⁺ c-Si:H (layers 310′ and 310″) by itself provides a very good surface passivation on p-type Si substrates on layer 305, such that the further addition of the SAM (layers 315′ and 315″) results in negligible additional improvement in surface passivation. Next, structures 307 and 308 were both exposed to hot (80° C.) 0.5M sulfuric acid for ˜24 hours under luminance of ˜400 nits. After exposure, only a small degradation is observed in the effective minority carrier lifetime (which is indicative of surface recombination velocity) was observed for structure 307, as indicated by line 312 of graph 309. This result demonstrates that layers 315′ and 315″ (which are SAMs) effectively protect the surface of the structure 307 against corrosion. In contrast, structure 308 exhibits significant degradation in the effective minority carrier lifetime after exposure, as indicated by line 313 of graph 309.

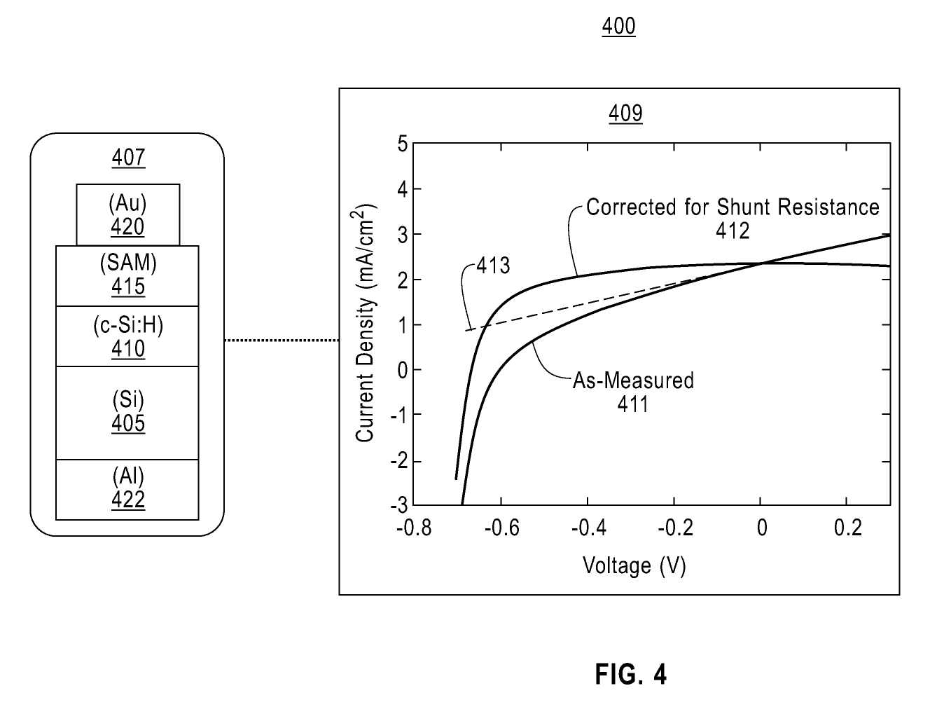

FIG. 4 is an example diagram of a photo-electrode test structure and the accompanying electrical characteristics measured under illumination which is subsequently used to estimate the applied bias photo-to-current efficiency (ABPE) associated with the test structure, in accordance with an embodiment of the present invention.

Test experiment 400 contains test structure 407 for measuring the electrical characteristics of the test structure under illumination. Test structure 407 is comprised of a top metal pad 420 (gold (Au) in this example); layer 405 (i.e., an absorption layer identical to layer 105, comprised of p-type single-crystalline Si in this example); layer 410 (i.e., hydrogenated crystalline silicon identical to layer 110, comprised of n+ c-Si:H in this example); and layer 415 (i.e., a SAM identical to layer 115); and blanket metal back contact 422 (i.e., aluminum (Al)). Metal pad 420 is disposed over layer 415, wherein layer 415 is disposed over layer 410, wherein layer 410 is disposed over layer 405, and wherein layer 405 is disposed over blanket metal back contact 422, whereas blanket metal back contact 422 is disposed over (on the back-side) of the layer 405. Graph 409 is a plot of current density as a function of voltage under an illumination intensity of ˜30 mW/cm² (provided by a halogen lamp). The measured electrical characteristics of line 411 were corrected for shunt resistance (corresponding to the inverse slope of line 413), as indicated by line 412. From this graph, the applied bias photon-to-current efficiency (ABPE) predicted for the photo-cathode corresponding to test structure 407 is calculated using:

$$ABPE = ( \frac{\vert j \vert \times ( 1.23 - \vert {V}_{b} \vert )}{1} ) \times 100 \% \qquad ( eq . 1 )$$

where j is the electrical current density (e.g. in the units of mA/cm²), I is the illumination intensity (e.g. in the units of mW/cm²) and V_{b} is the bias voltage.

Test structure 407 is exposed under an incident photon density of ˜30 mW/cm² (halogen lamp) and the predicted ABPE for a bias voltage of V_{b}=−0.4 V is ˜2.7%. In this illustrative example, metal pad 420 is a 0.25 mm² Au pad. As known in the art, ABPE can be improved by increasing the area coverage of metal pad 420, e.g. by using nano-structures.

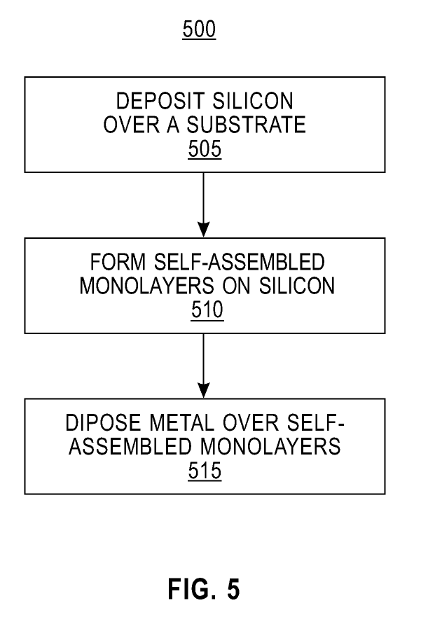

FIG. 5 is an operational flow chart depicting the functional steps to construct a photocathode, in accordance with an embodiment of the present invention.

Flowchart 500 describes the functional steps to construct a photo-electrode, such as photo-electrode 125. Fabrication processing involves the following techniques/processes applied on a semiconductor substrate which may be a silicon wafer (i.e., semiconductor fabrication)—lithography; etching; deposition; oxidation; chemical mechanical planarization; ion implantation; and diffusion. This is not an exhaustive list of techniques/processes included within fabrication processing but rather a list of commonly used techniques as understood in the art. Furthermore, the term “fabrication processing” implies a device or set of devices or any type of equipment used to implement the said techniques/processes, as understood in the art.

In step 505, fabrication processing invokes a plurality of process steps in order to deposit silicon over a substrate. In an exemplary embodiment, the deposited silicon is a c-Si:H layer and the substrate is a semiconductor, which includes silicon. In other embodiments, the substrate includes germanium or silicon-germanium. The substrate serves an absorption layer (e.g., layer 105, layer 305, and layer 405). The deposited c-Si:H layer may be comprised of c-Si:H (e.g., layer 110, layer 310′, layer 310″, and layer 410). Prior to c-Si:H layer deposition, substrate cleaning and surface treatment (e.g. native oxide removal) may be performed, using techniques known in the art. In an exemplary embodiment, the c-Si:H layer is grown by PECVD from a mixture of precursor gas SiH₄ (or other gases in the SiₓH_{y} family), carrier H₂ gas, and dopants such that [H₂]/[SiH₄]>5. In another embodiment, hot-wire chemical vapor deposition (HWCVD) may be used instead of PECVD. In an exemplary embodiment where the desired c-Si:H layer is n-type, an n-type dopant gas such as phosphine is included in the gas mixture for c-Si:H layer growth. In another embodiment where the desired c-Si:H layer is p-type, a p-type dopant gas such as diborane or trimethyborane is included in the gas mixture for c-Si:H growth. In yet another embodiment where the desired c-Si:H layer is intrinsic, no dopant gas is included in the gas mixture. In one example, the active doping level in the c-Si:H layer is as high 2×20²⁰ cm³ as measured by sheet resistance.

The c-Si:H (e.g., layer 110, layer 310′, layer 310″, and layer 410) may have hydrogen (H) content in the range of 5-40 atomic percent. In some embodiments, the H content may be uniformly distributed in the c-Si:H layer (e.g., layer 110, layer 310′, layer 310″, and layer 410). In other embodiments, the H may not be uniformly distributed in c-Si:H (e.g., layer 110, layer 310′, layer 310″, and layer 410). In some embodiments, the H content has a distribution gradient towards the interface between the c-Si:H layer (e.g., layer 110, layer 310′, layer 310″, and layer 410) and the absorption layer (e.g., layer 105, layer 305, and layer 405). As known in the art, the hydrogen profile may be measured by secondary ion-mass spectrometry (SIMS). In some embodiments, the c-Si:H layer may further contain one or more of the following elements: deuterium (D), fluorine (F), chlorine (Cl), carbon (C), germanium (Ge), oxygen (O), and nitrogen (N). In some embodiments where c-Si:H layer contains Ge (i.e., c-SiGe:H films), Ge is introduced from a gas source such as GeH₄, such that [H₂]/([SiH₄]+[GeH₄])>5.

In step 510, fabrication processing invokes a plurality of process steps to form the self-assembled monolayers on silicon. The silicon may be comprised of c-Si:H layer (e.g., layer 110, layer 310′, layer 310″, and layer 410). The Si surface may be (further) hydrogen-terminated using techniques in the art, such as dipping the Si surface in dilute hydrofluoric acid (HF). The Si substrate may then be immersed in long-chained alcohol or thiol reagents and heated to elevated temperatures (e.g. 90-150° C.). Under these conditions, the long-chained alcohols or thiols react with the silicon on the surface of the c-Si:H layer to form silyl-ether or silyl-thioether bonds, respectively. These silyl-ether and silyl-thioether bonds passivate the surface of c-Si:H layer. Accordingly, self-assembled monolayers (e.g., layer 115, layer 315′, layer 315″, and layer 415) are formed on the c-Si:H layer (e.g., layer 110, layer 310′, layer 310″, and layer 410), where the c-Si:H layer is disposed over absorption layer (e.g., layer 105, layer 305, and layer 405); or the self-assembled monolayer is disposed directly over the absorption layer, in embodiments where the c-Si:H layer is not used.

In step 515, fabrication processing invokes a plurality of process steps to dispose metal over the self-assembled monolayers. Metals, such as layer 120, are coated over the self-assembled monolayers (e.g., layer 115, layer 315′, layer 315″, and layer 415). As described above, layer 120 is disposed over SAM (e.g., layer 115), which is disposed over c-Si:H (e.g., layer 110), which is disposed over absorption layer (e.g., layer 105) to construct photo-electrode 125. Metals may be deposited using techniques known in the art, including thermal evaporation, electron beam (e-beam) evaporation, and sputtering.

What is claimed:

1. A method, comprising:
providing an absorption layer comprised of a semiconductor material;
epitaxially growing a hydrogenated silicon layer on the absorption layer using chemical vapor deposition;
forming a plurality of self-assembled monolayers (SAMs) on the hydrogenated silicon layer; and
coating the plurality of SAMs with one or more metals.

2. The method of claim 1, wherein the hydrogenated silicon layer is grown from a gas mixture containing SiH₄ and H₂.

3. The method of claim 2, wherein the gas mixture further includes an n-type or p-type dopant gas.

4. The method of claim 1, wherein the hydrogenated silicon layer is grown by plasma-enhanced chemical vapor deposition at temperatures below 450° C.

5. The method of claim 1, wherein the hydrogenated silicon layer is grown by plasma-enhanced chemical vapor deposition at temperatures in the range of 150-250° C.

6. The method of claim 1, wherein forming the plurality of SAMs, comprises:
creating a silicon-oxygen bond on a silicon surface deriving from long-chain alcohols.

7. The method of claim 1, wherein forming the plurality of SAMs, comprises:
creating a silicon-sulfur bond on a silicon surface deriving from long-chain thiols.

8. A photo-electrode, comprising:
an absorption layer, wherein the absorption layer is comprised of a semiconductor material;
a plurality of self-assembled monolayers (SAMs) disposed on the absorption layer; and
a metal electrode disposed on a surface of the plurality of SAMs.

9. The photo-electrode of claim 8, wherein the absorption layer is comprised of silicon.

10. The photo-electrode of claim 8, wherein the plurality of SAMs, comprises:
silicon-oxygen bonds deriving from long-chain alcohols.

11. The photo-electrode of claim 8, wherein the plurality of SAMs, comprises:
silicon-sulfur bonds deriving from long-chain thiols.

12. A photo-electrode, comprising:
an absorption layer, wherein the absorption layer is comprised of a semiconductor material;
a hydrogenated crystalline silicon layer disposed on the absorption layer;
a plurality of self-assembled monolayers (SAMs) disposed on the hydrogenated crystalline silicon layer, wherein the hydrogenated crystalline silicon layer passivates the absorption layer; and
a metal electrode disposed on a surface of the plurality of SAMs.

13. The photo-electrode of claim 12, wherein the absorption layer is comprised of silicon.

14. The photo-electrode of claim 12, wherein the plurality of SAMs, comprises:
silicon-oxygen bonds deriving from long-chain alcohols.

15. The photo-electrode of claim 12, wherein the plurality of SAMs, comprises:
silicon-sulfur bonds deriving from long-chain thiols.

16. The photo-electrode of claim 12, wherein the absorption layer is doped with material which is opposite to a doping of the hydrogenated crystalline silicon layer.

17. The photo-electrode of claim 12, wherein the hydrogenated crystalline silicon layer has hydrogen content ranging from 5 to 40 atomic percent.

18. The photo-electrode of claim 12, wherein the hydrogenated crystalline silicon layer is 5-20 nanometers (nm) thick.

19. The photo-electrode of claim 12, wherein the absorption layer is a p-type material, and the photo-electrode is used as a photo-cathode for photo-electrolysis (photolysis).

20. The photo-electrode of claim 12, wherein the absorption layer is a n-type material, and the photo-electrode is used as a photo-anode for photo-electrolysis (photolysis).
